(19) United States
(12) Patent Application Publication
(10) Pub. No.: US 2008/0315223 A1
(43) Pub. Date: Dec. 25, 2008

(54) LIGHT EMITTING DEVICE AND METHOD OF MANUFACTURING THE SAME

(76) Inventors: Tae Yun Kim, Gwangju (KR); Hyo Kun Son, Gwangju (KR)

Correspondence Address: BIRCH STEWART KOLASCH & BIRCH, PO BOX 747, FALLS CHURCH, VA, 22040-0747, US

(21) Appl. No.: 12/145,152

(22) Filed: Jun. 24, 2008

(30) Foreign Application Priority Data
Jun. 25, 2007 (KR) 10-2007-0062003

(51) Int. Cl. H01L 33/00

(52) U.S. Cl. 257/94; 438/47; 257/E33.027

(57) ABSTRACT

Provided is a light emitting device comprising a first conductive type semiconductor layer, an active layer, a semiconductor layer comprising Al, a high-concentration semiconductor layer, a low-mole InₓGa₁₋ₓN layer, and a second conductive type semiconductor layer. The active layer is on the first conductive type semiconductor layer and emits light. The semiconductor layer comprising Al is on the active layer. The high-concentration semiconductor layer is on the semiconductor layer comprising Al. The low-mole InₓGa₁₋ₓN layer is on the high-concentration semiconductor layer. The second conductive type semiconductor layer is on the low-mole InₓGa₁₋ₓN layer.

### CROSS-REFERENCE TO RELATED APPLICATIONS

The present application claims priority under 35 U.S.C. 119 and 35 U.S.C. 365 to Korean Patent Application No. 10-2007-0062003 (filed on Jun. 25, 2007), which is hereby incorporated by reference in its entirety.

### BACKGROUND

Embodiments relate to a light emitting device and a method of manufacturing the light emitting device.

Light-emitting diodes are widely used as light-emitting devices.

Such a light emitting diode includes an N-type semiconductor layer, an active layer, and a P-type semiconductor layer that are stacked, in which the active layer emits light to the outside according to applied power.

### SUMMARY

Embodiments provide a light emitting device and a method of manufacturing the light emitting device that can improve light emitting efficiency.

In an embodiment, a light emitting device comprises: a first conductive type semiconductor layer; an active layer on the first conductive type semiconductor layer; a semiconductor layer comprising Al on the active layer; a high-concentration semiconductor layer on the semiconductor layer comprising Al; a low-mole InₓGa₁₋ₓN layer on the high-concentration semiconductor layer; and a second conductive type semiconductor layer on the low-mole InₓGa₁₋ₓN layer.

In an embodiment, a light emitting device comprises: a first conductive type semiconductor layer; an active layer on the first conductive type semiconductor layer; a high-concentration semiconductor layer on the active layer; a low-mole InxGa1−xN layer comprising an uneven top on the high-concentration semiconductor layer; and a second conductive type semiconductor layer on the low-mole InₓGa₁₋ₓN layer.

In an embodiment, a method of manufacturing a light emitting device comprises: forming a first conductive type semiconductor layer; forming an active layer on the first conductive type semiconductor layer; forming a semiconductor layer comprising Al on the active layer; forming a high-concentration semiconductor layer on the semiconductor layer comprising Al; forming a low-mole InₓGa₁₋ₓN layer comprising a low quantity of indium on the high-concentration semiconductor layer; and forming a second conductive type semiconductor layer on the low-mole InₓGa₁₋ₓN layer.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating a light-emitting device according to an embodiment.

FIGS. 2 to 4 are cross-sectional views illustrating a method of manufacturing a light-emitting device according to an embodiment.

### DETAILED DESCRIPTION OF THE EMBODIMENTS

Hereinafter, a light-emitting device and a method of manufacturing the same according to embodiments will now be described in detail with reference to the accompanying drawings.

In the description of the embodiments, it will be understood that when an element is referred to as being ‘on/under’ another element, it can be directly on the another element, or it can be indirectly on the another element with an intervening element.

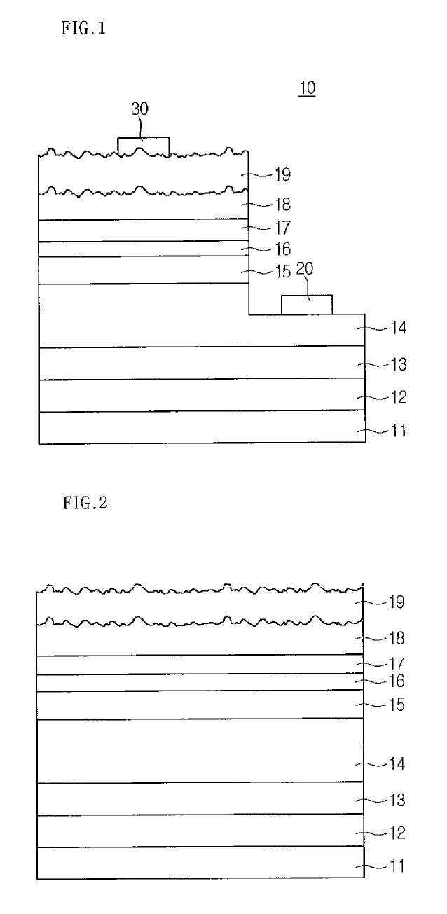

FIG. 1 is a cross-sectional view illustrating a light-emitting device according to an embodiment.

Referring to FIG. 1, a light emitting device 10 includes a substrate 11, a buffer layer 12, an un-doped GaN layer 13, a first conductive type semiconductor layer 14, an active layer 15, a nitride semiconductor layer 16, a high-concentration semiconductor layer 17, a low-mole InₓGa₁₋ₓN layer 18, a second conductive type semiconductor layer 19, a first electrode layer 20, and a second electrode layer 30. The buffer layer 12 is disposed on the substrate 11. The un-doped GaN layer 13 is disposed on the buffer layer 12. The first conductive type semiconductor layer 14 is disposed on the un-doped GaN layer 13. The active layer 15 is disposed on the first conductive type semiconductor layer 14. The nitride semiconductor layer comprising Al 16 is disposed on the active layer 15. The high-concentration semiconductor layer 17 is disposed on the nitride semiconductor layer comprising Al 16. The low-mole InₓGa₁₋ₓN layer 18 having a low quantity of indium is disposed on the high-concentration semiconductor layer 17. The second conductive type semiconductor layer 19 is disposed on the low-mole InₓGa₁₋ₓN layer 18. The first electrode layer 20 and the second electrode layer 30 are disposed on the first conductive type semiconductor layer 14 and the second conductive type semiconductor layer 19, respectively.

The light emitting device 10 includes a plurality of protrusions formed on a top of the second conductive type semiconductor layer 19. That is, the top of the second conductive type semiconductor layer 19 includes a plurality of concave and convex portions that are random in size and shape.

The high-concentration semiconductor layer 17 can be formed of N⁺⁺GaN that includes a high-concentration Si.

Since the low-mole InₓGa₁₋ₓN layer 18 disposed on the high-concentration semiconductor layer 17 grows unevenly, the top of the second conductive type semiconductor layer 19 is also uneven. The ‘x’ ranges from 0.05 to 0.1 in the low-mole InₓGa₁₋ₓN layer 18.

The nitride semiconductor layer comprising Al 16 can be formed of AlGaN that has a thickness ranging from about 150 Å to 200 Å.

AlgaN of the nitride semiconductor layer 16 prevents Si atoms of the high-concentration semiconductor layer 17 from being diffused into the active layer 15, thereby preventing a leakage current.

Light generated in the active layer 15 is emitted to the outside through the second conductive type semiconductor layer 19. Since the active layer 15 has a refraction index of about 2.33, and air has a refraction index of about 1, an incident angle of the light to be emitted to the outside must be about 23 degrees or less on the interface between the top of the second conductive type semiconductor layer 19 and air.

In this embodiment, since the plurality of concave and convex portions are formed in the top of the second conductive type semiconductor layer 19, the possibility is increased that the incident angle of the light on the top of the second conductive type semiconductor layer 19 is about 23 degrees or less.

Thus, the plurality of concave and convex portions formed in the top of the second conductive type semiconductor layer 19 can improve the optical efficiency of the light emitting device 10.

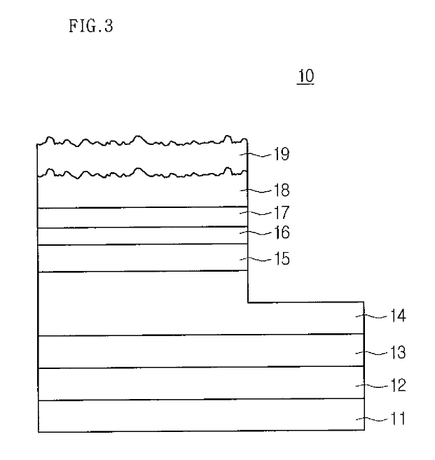

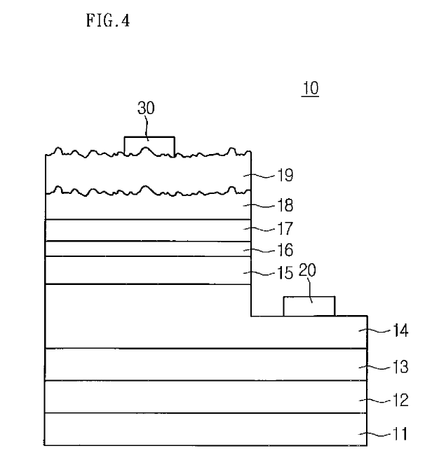

FIGS. 2 to 4 are cross-sectional views illustrating a method of manufacturing a light-emitting device according to an embodiment.

Referring to FIG. 2, a substrate 11 is provided, and then a buffer layer 12, an un-doped GaN layer 13, a first conductive type semiconductor layer 14, an active layer 15, a nitride semiconductor layer comprising Al 16, a high-concentration semiconductor layer 17, a low-mole InₓGa₁₋ₓN layer 18, and a second conductive type semiconductor layer 19 are formed on the substrate 11.

The substrate 11 can be formed of any one of sapphire, SiC, Si, GaAs, ZnO, and MgO. The buffer layer 12 can be formed in any one of an AlInN/GaN stack structure, an InₓGa₁₋ₓN/GaN stack structure, and an AlₓIn_{y}Ga_{1-(x+y)}N/InₓGa₁₋ₓN/GaN stack structure.

Trimethyl gallium (TMGa) and NH₃ are supplied to form the un-doped GaN layer 13, in which N₂ and H₂ can be used as a purge gas and a carrier gas.

The first conductive type semiconductor layer 14 can be formed Si—In co-doped GaN into which both silicon and indium are simultaneously dopped, and is formed as an N-type semiconductor layer.

The active layer 15 can be an InGaN layer formed through supplying NH₃, trimethyl gallium (TMGa), and trimethyl indium (TMIn).

The active layer 15 can be formed in an InGaN well layer/InGaN barrier layer structure with elements of InGaN differentiated in mole ratio.

The nitride semiconductor layer comprising Al 16 is formed on the active layer 15.

The nitride semiconductor layer comprising Al 16 can be formed as an AlGaN layer having a thickness ranging from about 150 Å to 200 Å at a temperature ranging from about 800° C. to 900° C. Also, when the high-concentration semiconductor layer 17 into which a high-concentration Si is implanted, is formed on the nitride semiconductor layer comprising Al 16, the high-concentration semiconductor layer 17 has a thickness to prevent high-concentration impurities drawn into the active layer 15, but not to affect an operation voltage.

The high-concentration semiconductor layer 17 is formed on the nitride semiconductor layer comprising Al 16.

The high-concentration semiconductor layer 17 is deposited for a period of time ranging from about 1 minute to 3 minutes and can be formed of N⁺⁺GaN to which the high-concentration Si is added. Si atoms are implanted with a concentration ranging from about 1×10¹⁸/cm³ to 9×10¹⁸/cm³.

As Si atoms are implanted with a high concentration, defects are increased. The defects cause a surface of the low-mole InₓGa₁₋ₓN layer 18 to be more uneven.

Then, the low-mole InₓGa₁₋ₓN layer 18 having a low quantity of indium is formed on the high-concentration semiconductor layer 17.

The low-mole InₓGa₁₋ₓN layer 18 grows in a spiral shape to have an uneven surface.

The second conductive type semiconductor layer 19 is formed on the low-mole InₓGa₁₋ₓN layer 18.

The second conductive type semiconductor layer 19 can be formed of GaN into which magnesium (Mg) is doped, and is formed as a P-type semiconductor layer.

Since the second conductive type semiconductor layer 19 grows along the uneven surface of the low mole InₓGa₁₋ₓN layer 18, a top of the second conductive type semiconductor layer 19 is also uneven.

Referring to FIGS, 3 and 4, the second conductive type semiconductor layer 19, the low-mole InₓGa₁₋ₓN layer 18, the high-concentration semiconductor layer 17, the nitride semiconductor layer comprising Al 16, the active layer 15, and the first conductive type semiconductor layer 14 are selectively removed.

Then, a first electrode layer 20 is formed on the first conductive type semiconductor layer 14, and a second electrode layer 30 is formed on the second conductive type semiconductor layer 19.

A bottom of the second electrode layer 30 can include a plurality of concave and convex portions according to the state of the top of the second conductive type semiconductor layer 19.

The active layer 15 of the light emitting device 10 emits light when power is applied to the first electrode layer 20 and the second electrode layer 30.

In the light emitting device 10, the uneven top of the second conductive type semiconductor layer 19 can more effectively emit the light generated from the active layer 15 to the outside, without disappearing of the light in the light emitting device 10.

Also, the nitride semiconductor layer 16 is formed on the active layer 15, to prevent the leakage current.

According to the embodiments, at least one of a third conductive type semiconductor layer and a transparent electrode layer can be formed on the second conductive type semiconductor layer. For example, the transparent electrode layer can be formed of one of ITO, ZnO, IrOₓ, RuOₓ, and NiO, and the third conductive type semiconductor layer can be formed as an N-type nitride semiconductor layer or a P-type nitride semiconductor layer.

According to the embodiments, the light emitting device and the method of manufacturing the same can improve light emitting efficiency.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a first conductive type semiconductor layer;
an active layer on the first conductive type semiconductor layer;
a semiconductor layer comprising Al on the active layer;
a high concentration semiconductor layer on the semiconductor layer comprising Al;
a low-mole InₓGa₁₋ₓN layer on the high-concentration semiconductor layer; and
a second conductive type semiconductor layer on the low-mole InₓGa₁₋ₓN layer.

2. The light emitting device according to claim 1, wherein the semiconductor layer comprising Al comprises an AlGaN layer.

3. The light emitting device according to claim 1, wherein the semiconductor layer comprising Al has a thickness ranging from 150 Å to 200 Å.

4. The light emitting device according to claim 1, wherein the high-concentration semiconductor layer comprises a heavily doped N-type impurities thereinto.

5. The light emitting device according to claim 1, wherein the high-concentration semiconductor layer comprises Si having a concentration ranging from 1×10¹⁸/cm³ to 9×10¹⁸/cm³.

6. The light emitting device according to claim 1, wherein the x in the low-mole InₓGa_{1×x}N layer ranges from 0.05 to 0.1.

7. The light emitting device according to claim 1, wherein the second conductive type semiconductor layer comprises an uneven top surface.

8. The light emitting device according to claim 1, wherein the semiconductor layer comprising Al is formed directly on the active layer.

9. The light emitting device according to claim 1, wherein the high-concentration semiconductor layer is formed directly on the semiconductor layer comprising Al.

10. The light emitting device according to claim 1, wherein the low-mole InₓGa₁₋ₓN layer is formed directly on the high-concentration semiconductor layer.

11. A light emitting device comprising:
a first conductive type semiconductor layer;
an active layer on the first conductive type semiconductor layer;
a high-concentration semiconductor layer on the active layer;
a low mole InₓGa₁₋ₓN layer comprising an uneven top on the high-concentration semiconductor layer; and
a second conductive type semiconductor layer on the low-mole InₓGa₁₋ₓN layer.

12. The light emitting device according to claim 11, comprising a semiconductor layer comprising Al between the active layer and the high-concentration semiconductor layer.

13. The light emitting device according to claim 11, wherein the high-concentration semiconductor layer comprises Si having a concentration ranging from 1×10¹⁸/cm³ to 9×10¹⁸/cm³.

14. The light emitting device according to claim 11, wherein the second conductive type semiconductor layer comprises an uneven top surface.

15. The light emitting device according to claim 12, wherein the semiconductor layer comprising Al has a thickness ranging from 150 Å to 200 Å.

16. A method of manufacturing a light emitting device, the method comprising:
forming a first conductive type semiconductor layer;
forming an active layer on the first conductive type semiconductor layer;
forming a semiconductor layer comprising Al on the active layer;
forming a high-concentration semiconductor layer on the semiconductor layer comprising Al;
forming a low-mole InₓGa₁₋ₓN layer comprising a low quantity of indium on the high-concentration semiconductor layer; and
forming a second conductive type semiconductor layer on the low-mole InₓGa₁₋ₓN layer.

17. The method according to claim 16, wherein the semiconductor layer comprising Al comprises an AlGaN layer having a thickness ranging from 150 Å to 200 Å at a temperature ranging from 800° C. to 900° C.

18. The method according to claim 16, wherein the low-mole InₓGa₁₋ₓN layer grows in a spiral shape to comprise an uneven surface.

19. The method according to claim 16, wherein the high-concentration semiconductor layer comprises Si that is implanted at a concentration ranging from 1×10¹⁸/cm³ to 9×10¹⁸/cm³.

20. The method according to claim 16, wherein the second conductive type semiconductor layer comprises a top that comprises various concave and convex portions depending on a concentration of Si implanted into the high concentration semiconductor layer.
